(19) United States
(12) Patent Application Publication
(10) Pub. No.: US 2013/0299901 A1
(43) Pub. Date: Nov. 14, 2013

(54) TRENCH MOSFET STRUCTURES USING THREE MASKS PROCESS

(71) Applicant: Force Mos Technology Co., Ltd., New Taipei City (TW)

(72) Inventor: FU-YUAN HSIEH, New Taipei City (TW)

(73) Assignee: Force Mos Technology Co., Ltd., New Taipei City (TW)

(21) Appl. No.: 13/949,336

(22) Filed: Jul. 24, 2013

Related U.S. Application Data
(63) Continuation-in-part of application No. 13/248,479, filed on Sep. 29, 2011, now Pat. No. 8,530,313.

(51) Int. Cl. H01L 29/78; H01L 29/66

(52) U.S. Cl. CPC H01L 29/7813; H01L 29/66734
USPC 257/330; 438/270

(57) ABSTRACT

A trench MOSFET comprising a plurality of trenched gates surrounded by source regions encompassed in body regions in active area. A plurality of trenched source-body contact structure penetrating through the source regions and extending into the body regions, are filled with tungsten plugs padded with a Ti layer, a first and a second TiN layer, wherein the second TiN layer is deposited after Ti silicide formation to avoid W spiking occurrence.

### CROSS REFERENCE TO RELATED APPLICATIONS

This application is a Continuation-In-Part (CIP) of U.S. patent application Ser. No. 13/248,479 of the same inventor, filed on Sep. 29, 2011, entitled “METHOD OF MANUFACTURING TRENCH MOSFET STRUCTURES USING THREE MASKS PROCESS”, which is a divisional of U.S. patent application Ser. No. 12/654,327 filed on Dec. 17, 2009, now U.S. Pat. No. 8,058,685, which is a Continuation-In-Part of U.S. patent application Ser. No. 12/458,293 filed on Jul. 8, 2009, now U.S. Pat. No. 7,816,720.

### FIELD OF THE INVENTION

This invention relates generally to the cell structures and device configuration of power semiconductor devices. More particularly, this invention relates to a novel and improved trench MOSFET (metal oxide semiconductor field effect transistor, the same hereinafter).

### BACKGROUND OF THE INVENTION

Please refer to FIG. 1A for an active area of an N-channel trench MOSFET of a prior art (U.S. Pat. No. 6,888,196) with n+ source regions 104 having a same surface doping concentration and junction depth along sidewalls of a trenched source-body contact structure 106 and channel region at a same distance from a top surface of the n+ source regions 104. The disclosed N-channel trench MOSFET is formed in an N epitaxial layer 102 supported on an N+ substrate 100. Below the n+ source regions 106, P body regions 103 are extending between two adjacent trenched gates 105. As mentioned above, the n+ source regions 104 have a same surface doping concentration and a same junction depth (Ds, as illustrated in FIG. 1A) along their top surface, which is related to the formation process of the n+ source regions 104.

FIG. 1B shows the formation process of the n+ source regions 104 in FIG. 1A. After the formation of the P body regions 103 and their diffusion, the n+ source regions 104 are formed by performing source dopant ion implantation through a source mask (not shown). The whole top surface of the P body regions 103 suffered the same source dopant ion implantation and the same source dopant vertical diffusion step, therefore the n+ source regions 104 have the same doping concentration and the same junction depth at the same distance from their top surface.

This uniform contribution of doping concentration and junction depth of the source regions may lead to a hazardous failure during UIS (Unclamped Inductive Switching) test, please refer to FIG. 1C for a top view of a cell structure comprising the trenched source-body contact structure 106 and the n+ source regions 104 surrounding around shown in FIG. 1A. As illustrated, R_{be} is the base resistance from the trenched source-body contact structure 106 to a cell corner; R_{be} is the base resistance from the trenched source-body contact structure 106 to a cell edge. Obviously, R_{be} is greater than R_{be} because the distance from the trenched source-body contact structure 106 to the cell corner is longer than that from the trenched source-body contact structure 106 to the cell edge, resulting in UIS failure occurring at a trench corner of the trenched gate and a poor avalanche capability.

Accordingly, it would be desirable to provide a new and improved device configuration to resolve these difficulties and design limitations.

### SUMMARY OF THE INVENTION

The present invention has been conceived to solve the above-described problems with the related art, and it is an object of the invention to provide a technique which makes it possible to reduce the area occupied by cells to be formed on a substrate, thereby following a reduction of the size of devices.

In order to solve the above-described problems, according to a first aspect of the invention, there is provided a trench semiconductor power MOSFET comprising a plurality of transistor cells with each cell composed of a plurality of first trenched gates with each surrounded by a source region heavily doped with a first conductivity type in active area encompassed in a body region of a second conductivity type above a drain region disposed on a bottom surface of a low-resistivity substrate of the first conductivity type, wherein: the plurality of transistor cells formed in an epitaxial layer with said first conductivity type over the low-resistivity substrate, and with a lower doping concentration than the low-resistivity substrate; the source region has doping concentration along channel region lower than along sidewalls of a trenched source-body contact structure at a same distance from the surface of the epitaxial layer, and source junction depth is shallower along the channel region than along the sidewalls of the trenched source-body contact structure, and the doping profile of the source region along the surface of the epitaxial layer has Gaussian-distribution from the trenched source-body contact structure to the channel region, as shown in FIG. 2A; the plurality of first trenched gates filled with doped poly-silicon padded with a first insulation layer as gate oxide. Each the transistor cell further comprises: at least a second trenched gate having a wider trench width than the first trenched gates and filled with the doped poly-silicon padded with the first insulation layer as gate oxide; a second insulation layer functioning as contact interlayer; a plurality of trenched source-body contact structures penetrating through the second insulation layer and the source region, and extending into the body regions to contact both the source region and the body region; at least a trenched gate contact structure penetrating through the second insulation layer and extending into the doped poly-silicon in the second trenched gate; a body contact area heavily doped with the second conductivity type around bottom of each the trenched source-body contact structure; a source metal connected to the source region and the body regions; a gate metal connected to the second trenched gate.

According to an added feature of the present invention, in some preferred embodiments, the dopant of the source region is diffused to just reach the cell edge, please refer to FIG. 2B for a top view of an N-channel trench MOSFET structure, the dash-dotted line illustrates the area of the n+ source region with a doping concentration no less than 1×10¹⁹ cm⁻³. At cell corners, the n region has a lower doping concentration due to the Gaussian-distribution, which is less than 1×10¹⁹ cm⁻³. Therefore, s Source Ballast Resistance (SBR) of the n region exists at cell corners, which reduces the Emitter injection efficiency of the parasitic NPN bipolar transistors (as illustrated in FIG. 1A), thus rendering it difficult to turn on, avoiding the UIS failure issue and improving the avalanche capability. In other preferred embodiments, the dopant of the source region is diffused further after reaching the cell edge to optimize trade-off between R_{ds} (resistance between drain and source) and avalanche capability, please refer to FIG. 2C for another top view of an N-channel trench MOSFET structure. At the cell edge, the n+ source region is adjacent to the gate oxide, therefore the area of lower doped n region at the cell edge is smaller than that in FIG. 2B. It seems that the source resistance is reduced at cell corner, breaching the desire of enhancing the avalanche capability, however, as the Rd, is the same important, and it is reduced by shortening the distance of highly doped region to the cell edge, therefore, a trade-off is achieved between the avalanche capability and the R_{ds}, optimizing the device to a better performance.

According to an added feature of the present invention, in some preferred embodiments, as shown in FIG. 3A and FIG. 6, each of the plurality of trenched source-body contact structures has vertical sidewalls in the source regions and the body regions; in other preferred embodiments, as shown in FIG. 4 and FIG. 7, each of the plurality of trenched source-body contact structures has slope sidewalls in the source regions and the body regions; in other preferred embodiments, as shown in FIG. 5 and FIG. 8, each of the plurality of trenched source-body contact structures has vertical sidewalls in the source regions and has slope sidewalls in the body regions to enlarge the body contact area wrapping the slope trench sidewalls and the bottom to further improve device avalanche capability.

According to an added feature of the present invention, in some preferred embodiments, as shown in FIG. 3A, FIG. 4 and FIG. 5, each of the plurality of trenched source-body contact structures comprises a metal plug filling into a contact opening, wherein the metal plug is W (tungsten) plug padded by a barrier layer of Ti/TiN or Co/TiN or Ta/TiN and is contacting with the source metal which is padded by a resistance-reduction layer of Ti or TiN; in other preferred embodiments, as shown in FIGS. 6˜8, each of the plurality of trenched source-body contact structures comprises the source metal directly filling into a contact opening and serving as a metal plug to enhance the metal contact performance, wherein the source metal is padded by a barrier layer of Ti/TiN or Co/Tin or Ta/TiN.

According to an added feature of the present invention, in some preferred embodiments, the configuration of each of the transistor cells is square or rectangular closed cell, please refer to FIG. 9A, FIG. 10A, FIG. 11A and FIG. 14A for the top view of each of preferred closed cell; in other preferred embodiments, the configuration of each of the transistor cells is stripe cell, please refer to FIG. 12, FIG. 13 and FIG. 15 for the top view of each of preferred stripe cell.

According to an added feature of the present invention, in some preferred embodiments, as shown in FIG. 9B, FIG. 10B, FIG. 10C, FIG. 14B and FIG. 14C, the trench MOSFET further comprises a termination area comprising multiple trenched floating gates composed of a plurality of third trenched gates filled with the doped poly-silicon padded with the first insulation layer and surrounded by the body regions, and no source regions between two adjacent third trenched gates in the termination area.

According to an added feature of the present invention, in some preferred embodiments, as shown in FIG. 10B, each of the transistor cells further comprises at least a fourth trenched gate between the first trenched gates and the second trenched gate to block source dopant lateral diffusion at edge corner for improving avalanche capability, the fourth trenched gate is shorted with the source region and filled with the doped poly-silicon padded with the first insulation layer.

According to an added feature of the present invention, in some preferred embodiments, the plurality of trenched source-body contact structures in the active area have uniform width, please refer to FIG. 12 for a top view of a preferred transistor cell; in other preferred embodiment, among the plurality of trenched source-body contact structures, at least one column or raw cells near edge trench have greater width than the others, please refer to FIG. 13 and FIG. 14A for preferred transistor cells.

According to an added feature of the present invention, in some preferred embodiments, as shown in FIG. 9B and FIG. 10B, the body region between the second trenched gate and the adjacent first trenched gate is shorted with the source metal via a trenched edge contact structure; in other preferred embodiment, as shown in FIG. 14B, the body region between the second trenched gate and the adjacent first trenched gate has floating voltage as there is no trenched edge contact structure.

According to an added feature of the present invention, in some preferred embodiments, as shown in FIG. 17˜FIG. 19, a second TiN layer is added sandwiched between a barrier layer of Ti/TiN and a metal plug to avoid the possible TiN void occurring in corners of the trenched source-body contact structure.

The present invention further provides a method for manufacturing a trench MOSFET comprising a plurality of transistor cells with each comprising a plurality of trenched gates surrounded by source regions of a first conductivity type near a top surface of a silicon layer of the first conductivity type encompassed in body regions of a second conductivity type, the method comprising: depositing a contact interlayer on the top surface of the silicon layer; applying a contact mask and following with an etching process to remove the contact interlayer from contact openings defined by the contact mask; implanting the silicon layer with a source dopant of the first conductivity type through the contact openings and diffusing the source dopant to form the source regions in the contact openings, thereby a source mask is saved; carrying out a dry silicon etch to make the contact openings penetrating through the source regions and extending into the body regions; depositing a barrier layer of Ti and a first TiN layer along inner surface of the contact openings; performing a step of RTA or furnace anneal; depositing a second TiN layer onto the barrier layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a cross-sectional view of a trench MOSFET of prior art.

FIG. 1B is a cross-sectional view for showing the formation method of source region in prior art.

FIG. 1C is a top view of a trench MOSFET for showing the disadvantage of prior art.

FIG. 2A is a cross-sectional view for showing the formation method of source region according to the present invention.

FIG. 2B is a top view for showing a source region diffusion method according to the present invention.

FIG. 2C is a top view for showing another source region diffusion method according to the present invention.

FIG. 3A is a cross-sectional view of an N-channel trench MOSFET showing a preferred embodiment according to the present invention, which is also the X₁-X₁′ cross section in FIG. 2B.

FIG. 3B is the doping profiles for showing the relationship between depth from epitaxial surface and doping concentration in trenched source-body contact structure and channel region, respectively.

FIG. 3C is another cross-sectional view of the preferred embodiment shown in FIG. 3A for showing the X₂-X₂′ cross section in FIG. 2B.

FIG. 4 is a cross-sectional view of an N-channel trench MOSFET showing another preferred embodiment according to the present invention.

FIG. 5 is a cross-sectional view of an N-channel trench MOSFET showing another preferred embodiment according to the present invention.

FIG. 6 is a cross-sectional view of an N-channel trench MOSFET showing another preferred embodiment according to the present invention.

FIG. 7 is a cross-sectional view of an N-channel trench MOSFET showing another preferred embodiment according to the present invention.

FIG. 8 is a cross-sectional view of an N-channel trench MOSFET showing another preferred embodiment according to the present invention.

FIG. 9A is a top view of a preferred embodiment with closed cells according to the present invention.

FIG. 9B is a cross-sectional view of an N-channel trench MOSFET showing the A₁-B₁-C₁-D₁ cross section in FIG. 9A.

FIG. 10A is a top view of another preferred embodiment with closed cells according to the present invention.

FIG. 10B is a cross-sectional view of an N-channel trench MOSFET showing the A₂-B₂-C₂-D₂ cross section in FIG. 10A.

FIG. 10C is a cross-sectional view of an N-channel trench MOSFET showing the E-F-G cross section in FIG. 10A.

FIG. 11A is a top view of another preferred embodiment with closed cells according to the present invention.

FIG. 11B is a top view showing the different contact width in FIG. 11A, at least one column or raw cells near edge trench has wider contact width than others.

FIG. 11C is a cross-sectional view of an N-channel trench MOSFET showing the H-H′ cross section in FIG. 11B.

FIG. 12 is a top view of another preferred embodiment with stripe cells according to the present invention.

FIG. 13 is a top view of another preferred embodiment with stripe cells according to the present invention.

FIG. 14A is a top view of another preferred embodiment with closed cells according the present invention.

FIG. 14B is a cross-sectional view of an N-channel MOSFET showing the I-J-K-L cross section in FIG. 14A.

FIG. 14C is a cross-sectional view of an N-channel MOSFET showing the M-M′ cross section in FIG. 14A.

FIG. 15 is a top view of another preferred embodiment with stripe cells according to the present invention.

FIG. 16 is a cross-sectional view of another preferred embodiment according to the present invention.

FIG. 17 is a cross-sectional view of another preferred embodiment according to the present invention.

FIG. 18 is a cross-sectional view of another preferred embodiment according to the present invention.

FIG. 19 is a cross-sectional view of another preferred embodiment according to the present invention.

FIGS. 20A˜20E are a serial of cross-sectional view for showing the processing steps for fabricating the trench MOSFET as shown in FIG. 19.

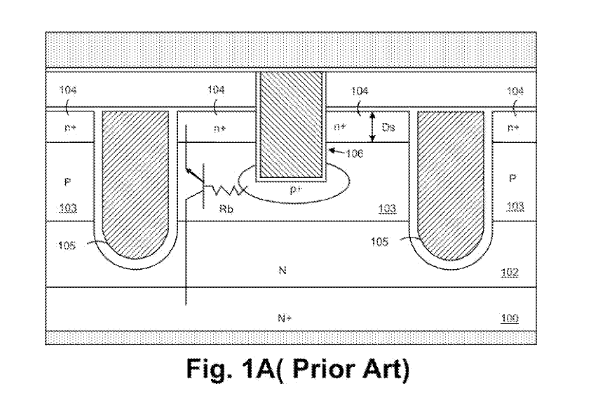

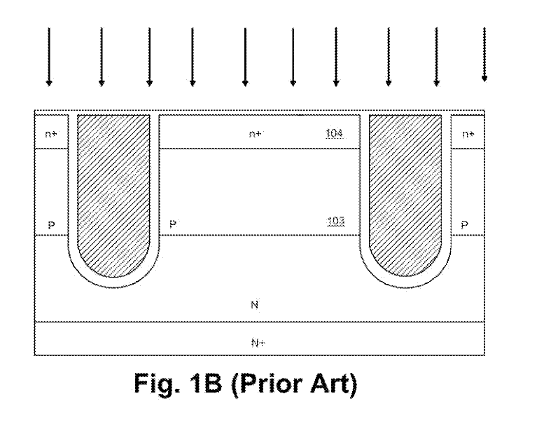

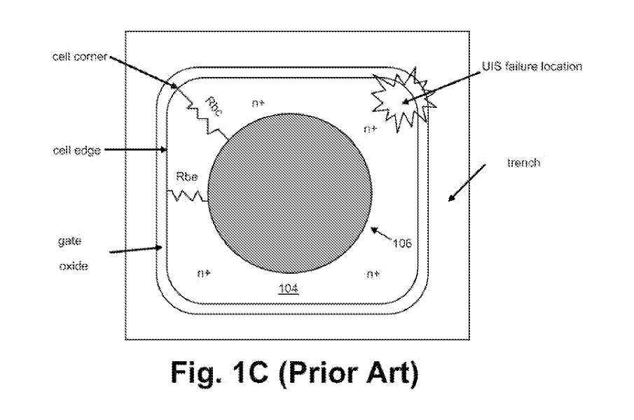

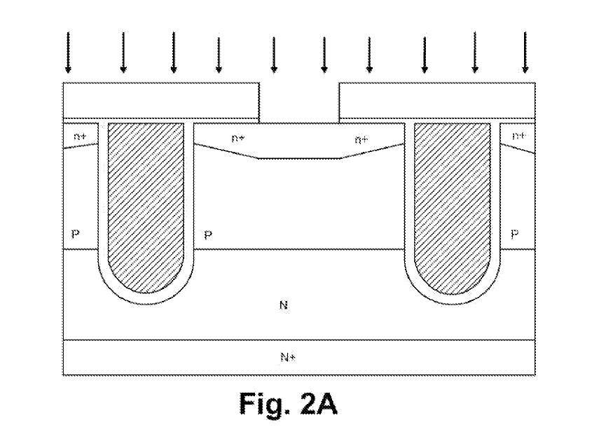

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

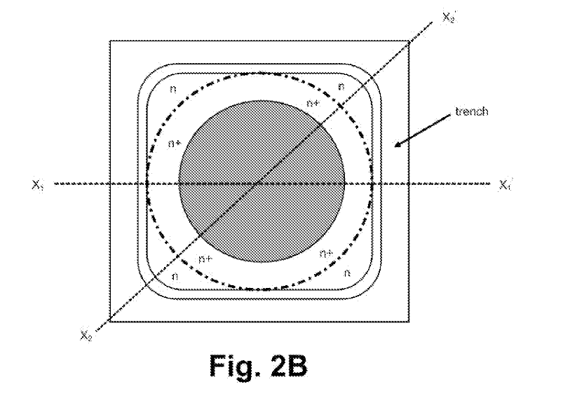

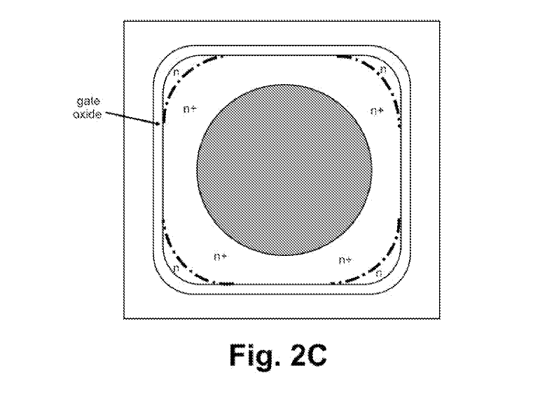

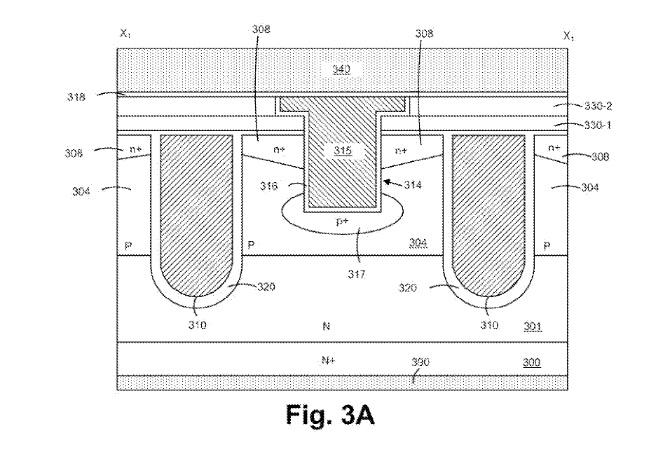

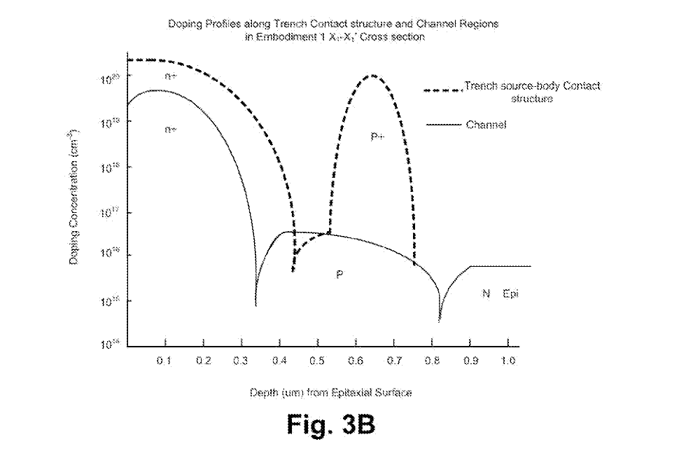

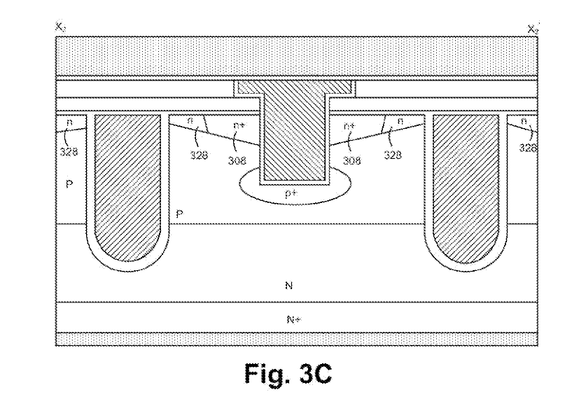

Please refer to FIG. 3A for a preferred embodiment of this invention, which also is the X₁-X₁′ cross section of FIG. 2B, where an N-channel trench MOSFET is formed on an N+ substrate 300 coated with back metal 390 of Ti/Ni/Ag on rear side as drain electrode. Onto said N+ substrate 300, a lighter doped N epitaxial layer 301 is grown, and a plurality of first trenched gates 310 filled with doped poly-silicon onto a gate oxide 320 are formed wherein. Near the top surface of P body regions 304, n+ source regions 308 are formed with Gaussian-distribution from sidewalls of a trenched source-body contact structure 314 to a channel region near the first trenched gate 310. Each the trenched source-body contact structure 314 comprises a metal plug 315 (which is a W plug in this embodiment) padded by a barrier layer 316 of Ti/TiN or Co/TiN or Ta/TiN and penetrating through a contact interlayer comprising a layer of un-doped SRO (Silicon Rich Oxide) 330-1 and a layer of BPSG (Boron Phosphorus Silicon Glass) or PSG (Phosphorus Silicon Glass) 330-2, and through the n+ source region 308 and extending into the P body region 304 with vertical sidewalls. Especially, the trenched source-body contact structure 314 has a greater width in the BPSG or PSG layer 330-2 than in other potion. Underneath bottom of the trenched source-body contact structure 314, a p+ body contact area 317 is implanted to further reduce the contact resistance between the metal plug 315 and the P body region 304. Onto a resistance-reduction layer 318 of Ti or Ti/TiN, a source metal 340 composed of Al alloys or Cu alloys is deposited to electrically contact with the metal plug 315.

In order to further make clear, FIG. 3B illustrates the doping profiles along the sidewalls of the trenched source-body contact structure 314 and the channel region from top surface of the N epitaxial layer 301 in the N-channel trench MOSFET shown in FIG. 3A. In FIG. 3B, n+ represents the n+ source region 308, P represents the P body region 304, and p+ represents the p+ body contact area 317. FIG. 3C shows the X₂-X₂′ cross section of FIG. 2B, in cell corners, n region 328 has a lower doping concentration and shallower junction depth than the n+ source region 308, resulting in a lower base resistance to further enhance avalanche capability.

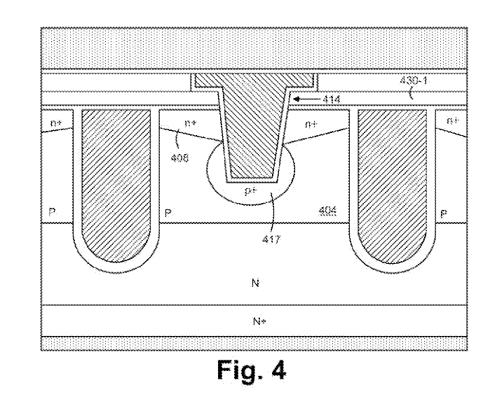

Please refer to FIG. 4 for another preferred embodiment of the present invention where the N-channel trench MOSFET is similar to that in FIG. 3A except that, each the trenched source-body contact structure 414 has slope sidewalls in P body regions 404, in n+ source regions 408 and in un-doped SRO layer 430-1. By employing this structure, p+ body contact area 417 is enlarged to wrap the slope sidewalls and the bottom of the trenched source-body contact structure 414 to further enhance avalanche capability.

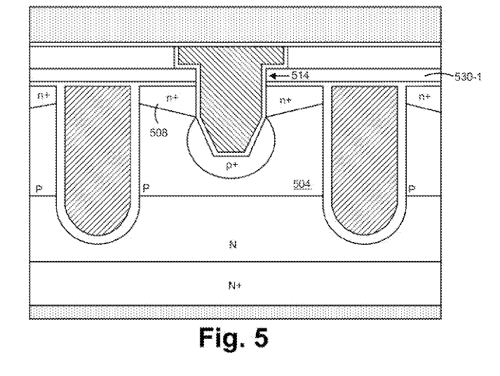

Please refer to FIG. 5 for another embodiment of the present invention where the N-channel trench MOSFET is similar to that in FIG. 4 except that, the trenched source-body contact structure 514 has slope sidewalls only in P body regions 504 and has vertical sidewalls in n+ source regions 508 and un-doped SRO layer 530-1 to prevent dopant neutralization may introduced by the slope sidewalls in the n+ source region in FIG. 4 when implanting p+ body contact area which will result in high source contact resistance.

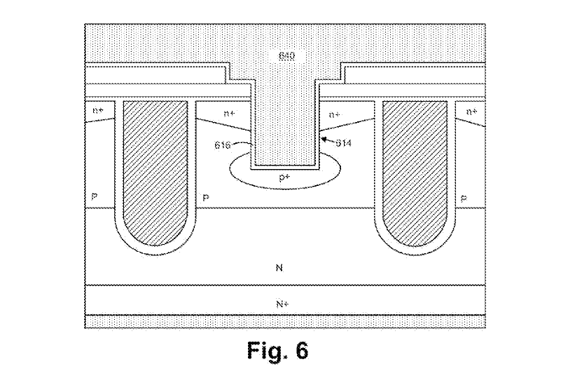

Please refer to FIG. 6 for a preferred embodiment of the present invention where the N-channel trench MOSFET is similar to that in FIG. 3A except that, each the trenched source-body contact structure 614 comprises a metal plug formed directly by filling a source metal 640 of Al alloys or Cu over a barrier layer 616 of Ti/TiN or Co/TiN or Ta/TiN.

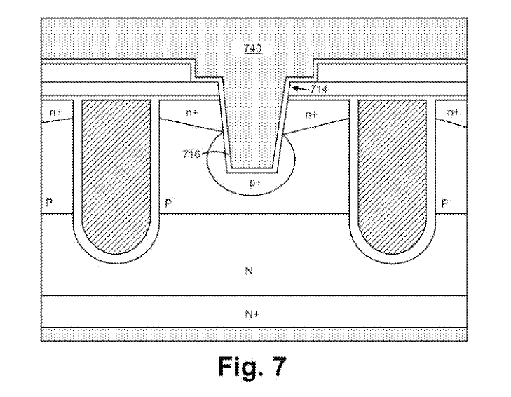

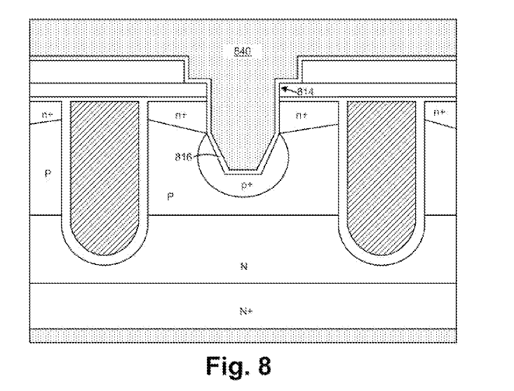

Please refer to FIG. 7 for a preferred embodiment of the present invention where the N-channel trench MOSFET is similar to that in FIG. 4 except that, each the trenched source-body contact structure 714 comprises a metla plug formed directly by filling source metal 740 of Al alloys or Cu over a barrier layer 716 of Ti/TiN or Co/TiN or Ta/TiN.

Please refer to FIG. 8 for a preferred embodiment of the present invention where the N-channel trench MOSFET is similar to that in FIG. 5 except that, each the trenched source-body contact structure 814 comprises a metal plug formed directly by filling a source metal 840 of Al alloys or Cu over a barrier layer 816 of Ti/TiN or Co/TiN or Ta/TiN.

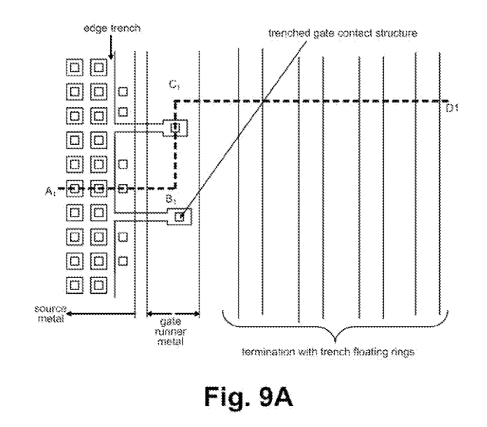

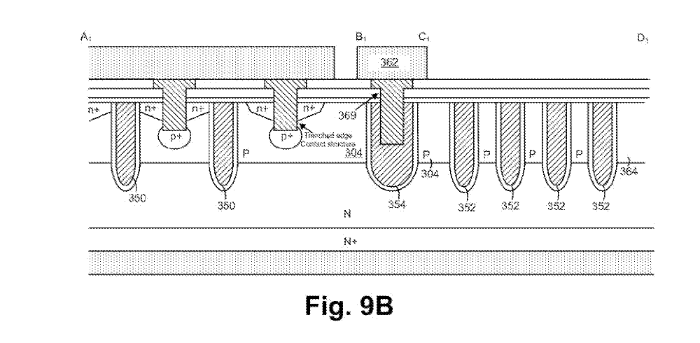

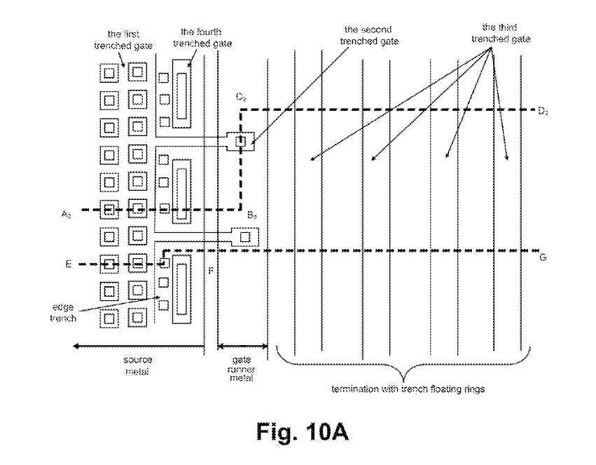

FIG. 9B shows an N-channel trench MOSFET with a termination area according to the present invention, which is also the A₁-B₁-C₁-D₁ cross section of FIG. 9A. The N-channel trench MOSFET in FIG. 9B has an active area same as FIG. 3A and a termination area comprising a plurality of third trenched floating gates 352 filled with doped poly-silicon over a gate oxide encompassed in P body regions without having n+ source regions wherein. Trench depth of the third trench floating gates 352 is equal to or greater than junction depth of the P body regions 364. Trench width of the third trench floating gates 352 is equal to or greater than that of the first trenched gates 350 in the active area. The N-channel trench MOSFET further comprises at least a wider second trenched gate 354 filled with the doped poly-silicon over the gate oxide between the active area and the termination area to connected to a gate metal 362 via a trenched gate contact structure 369 filled with W plug.

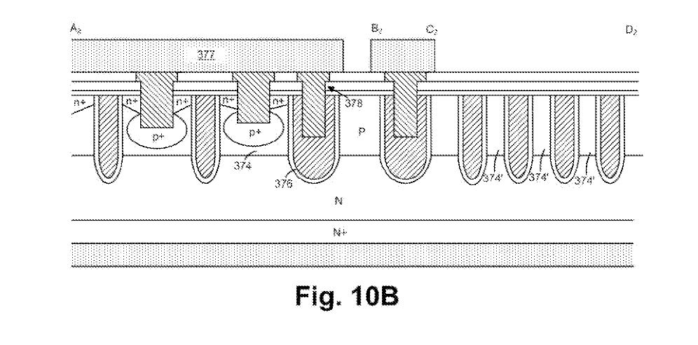

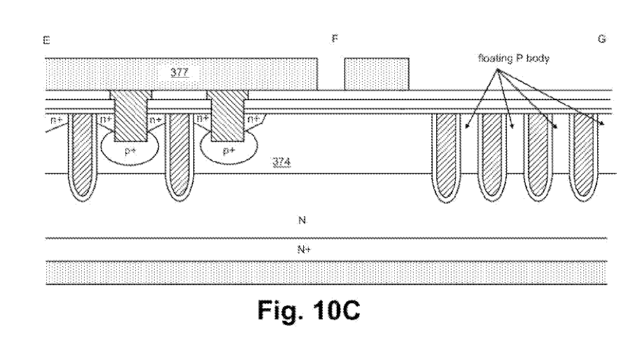

FIG. 10B shows an N-channel trench MOSFET with termination area according to the present invention, which is also the A₂-B₂-C₂-D₂ cross section of FIG. 10A. Comparing to FIG. 9B, the N-channel trench MOSFET in FIG. 10B further comprises a fourth trenched gate 376 to block n+ lateral diffusion at edge of the active area for improving avalanche capability. Furthermore, the fourth trenched gate 376 is shorted with a source metal 377 via a trenched edge contact structure 378. FIG. 10C shows the E-F-G cross section of FIG. 10A, from which we can see that, the P body region 374 next to the second trenched gate is shorted with the source metal 377 while the P body regions 374′ in termination area has floating voltage.

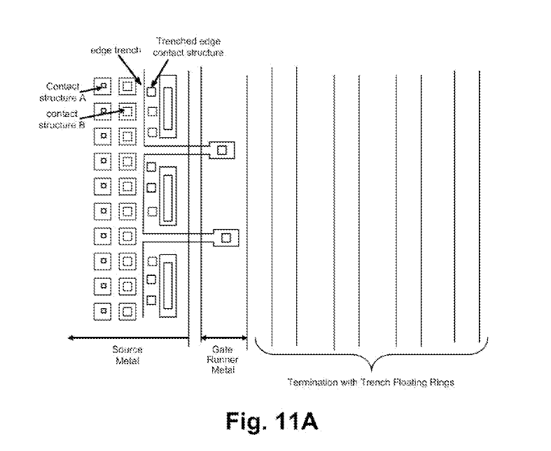

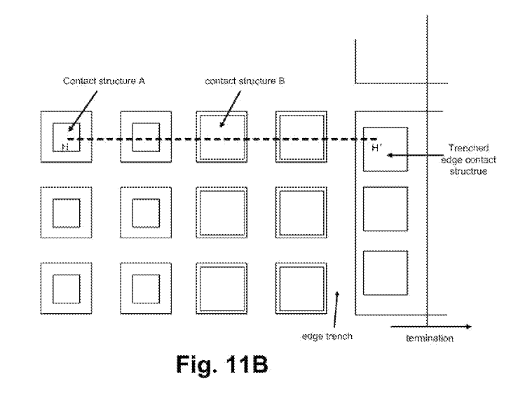

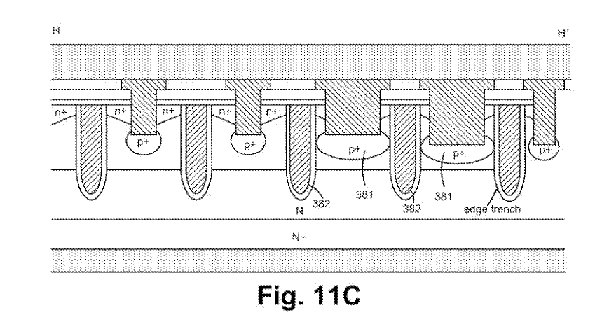

FIG. 11C shows a preferred active area of an N-channel trench MOSFET according to the present invention, which is also the H-H′ cross section of FIG. 11B showing the width of contact structure A (the same contact A in FIG. 11A) is smaller than width of contact structure B (the same contact B in FIG. 11A) adjacent to the edge trench. Therefore, in FIG. 11C, the p+ body contact area 381 underneath the trenched source-body contact structure in the first two cells adjacent to the edge trench serving as buffer cells is closer to the first trenched gate 382 than normal cells, and Vth of the buffer cells is thus higher due to the p+ body contact area 381 touching to channel region so that the buffer cells will not be turned on first when gate is biased.

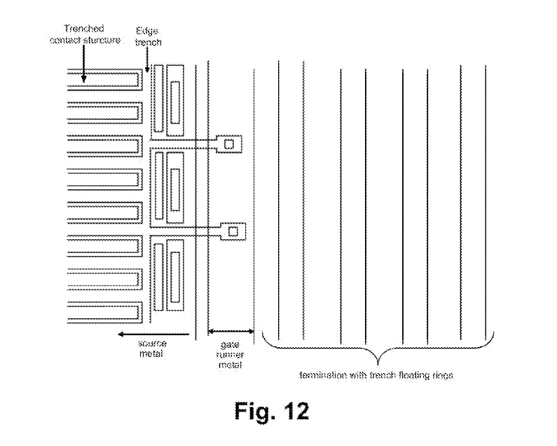

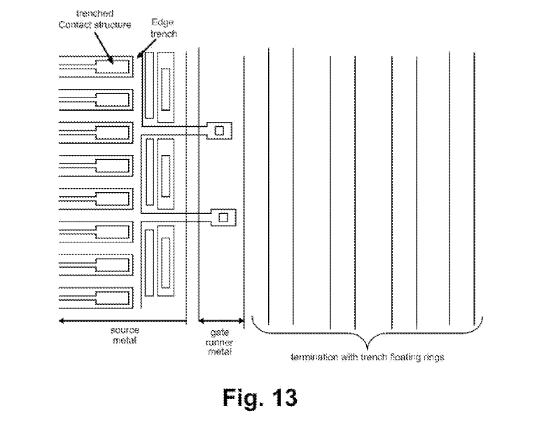

As the same to stripe cells, comparing to FIG. 12 with uniform trenched contact width in the active area, the top view in FIG. 13 shows the preferred embodiment with stripe cells having a greater trenched contact width near the edge trench.

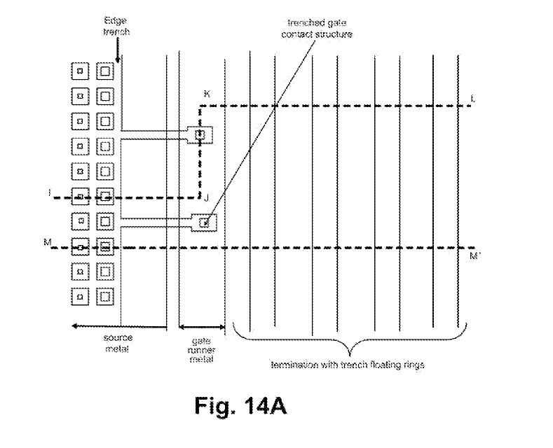

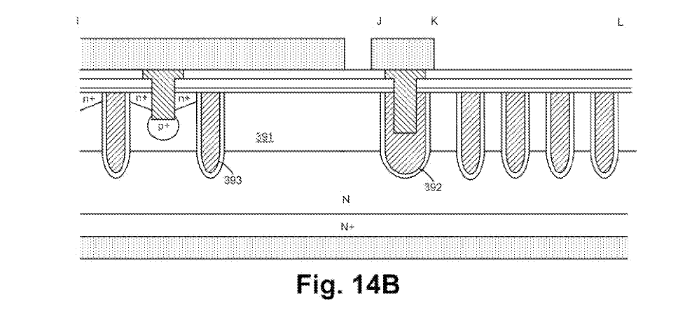

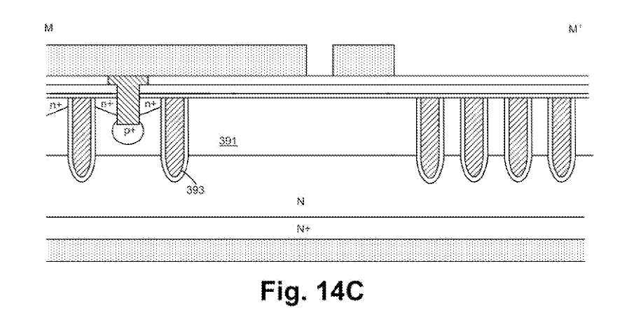

FIG. 14B shows an N-channel trench MOSFET with a termination area according to the present invention, which is also the I-J-K-L cross section in FIG. 14A. Comparing to FIG. 9B, the N-channel trench MOSFET in FIG. 14B does not have a trenched edge contact structure wherein, therefore the P body region 391 between the second trenched gate 392 and the adjacent first trenched gate 393 are floating, which can be also seen from FIG. 14C, the M-M′ cross section in FIG. 14A.

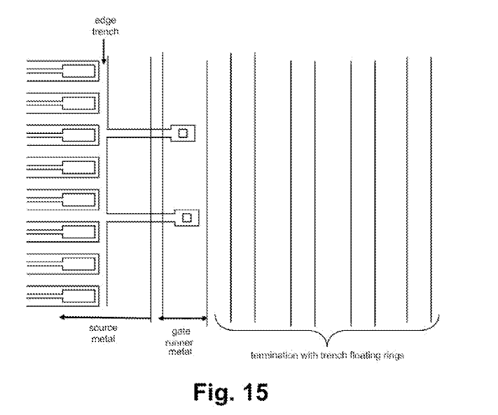

As the same to stripe cells, FIG. 15 shows the top view of an N-channel trench MOSFET without a trenched edge contact structure wherein.

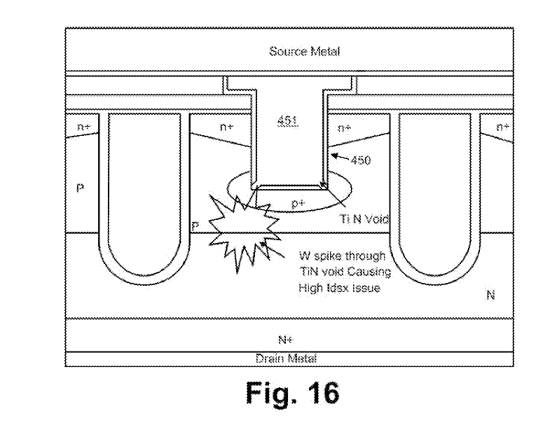

Please refer to FIG. 16 for a preferred embodiment of the present invention where the N-channel trench MOSFET is similar to that in FIG. 3A except that, sometimes TiN void is observed near corners of a trenched source-body contact structure 450 comprising a W plug 451 after RTA (Rapid Thermal Annealing) or furnace anneal (for formation of Ti silicide along sidewalls and bottom of the trenched source-body contact structure), causing high Idsx due to W spiking through the TiN void.

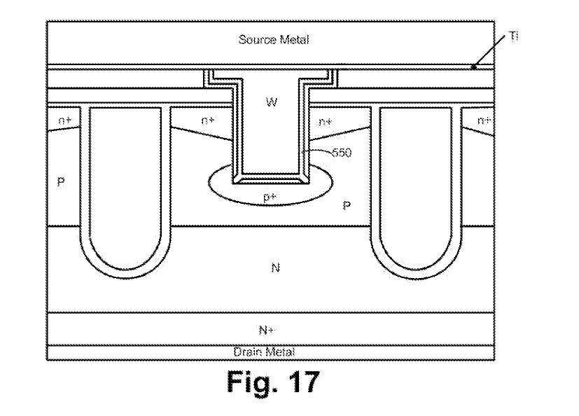

Please refer to FIG. 17 for a preferred embodiment of the present invention where the N-channel trench MOSFET is similar to that in FIG. 16 except that, a second TiN layer 550 is added onto the Ti/TiN layer to resolve the W spiking issue happened in FIG. 16, which can be implemented by depositing a second TiN layer 550 after Ti and the first TiN layer deposition and the RTA or the furnace anneal. When the metal plug of the trenched source-body contact structure is implemented by directly depositing a source metal (not shown, please refer to FIG. 6), a source metal spiking issue also can be avoided by using the inventive second TiN layer.

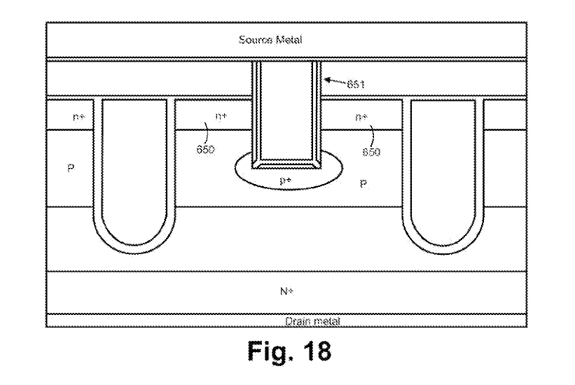

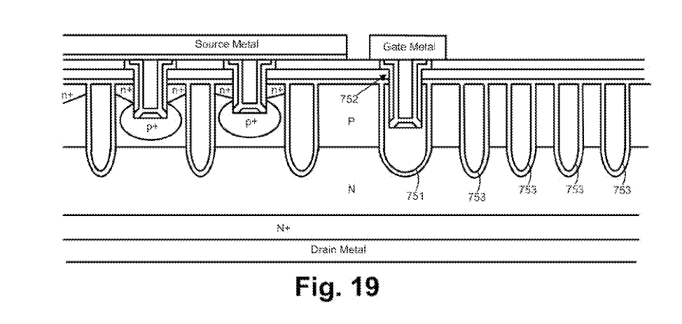

Please refer to FIG. 18 for a preferred embodiment of the present invention where the N-channel trench MOSFET is similar to that in FIG. 17 except that, the n+ source regions 650 has uniform distribution from sidewalls of the trenched source-body contact structure 651 to adjacent channel region.

Please refer to FIG. 19 for another preferred embodiment of the present invention where the N-channel trench MOSFET has an active area similar to that in FIG. 17 except further comprising: at lease a second wider trenched gate 751 connected to a gate metal via a trenched gate contact structure 752; a termination area composed of multiple of third trenched floating gates 753. Wherein the trenched gate contact structure 752 is filled with a W plug padded by: Ti/TiN layer and a second TiN layer whereon.

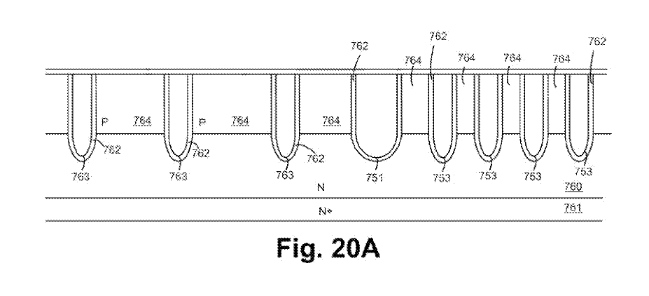

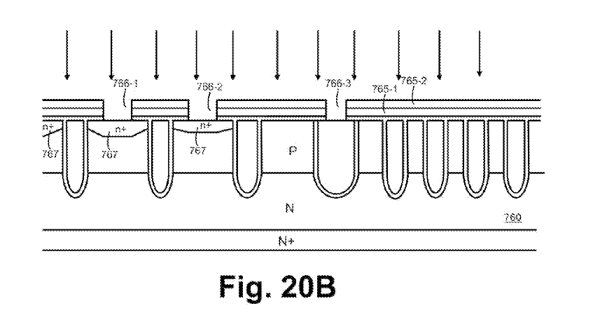

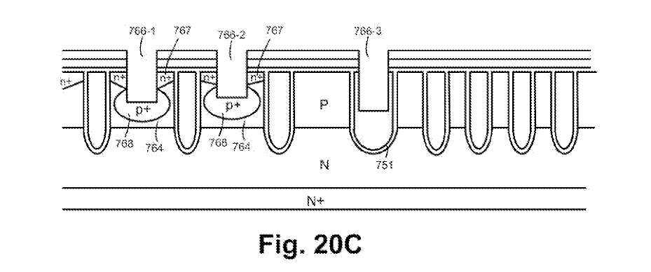

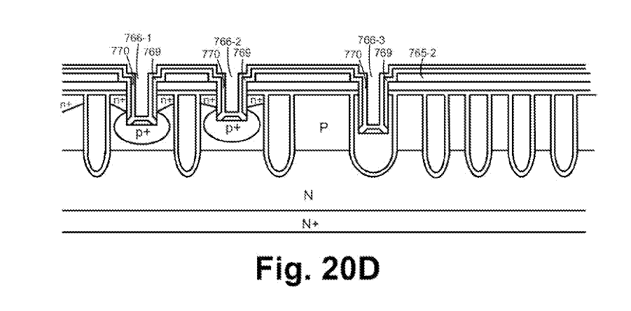

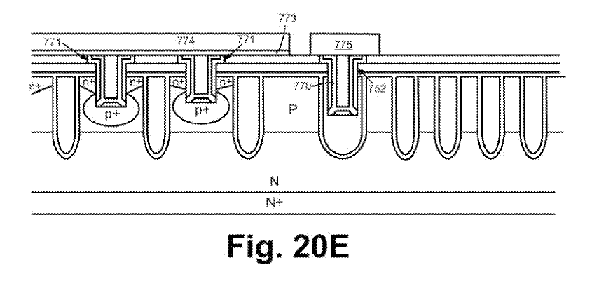

FIGS. 20A to 20E are a serial of exemplary steps that are performed to form the preferred N-channel trench MOSFET in FIG. 19. In FIG. 20A, an N doped epitaxial layer 760 is grown on an N+ substrate 761. After applying a trench mask (not shown), a plurality of gate trenches are etched to a certain depth into the N epitaxial layer 760. Then, a sacrificial oxide layer (not shown) is grown and then removed to eliminate the plasma damage may introduced during the gate trenches etching process. Next, a first insulation layer is deposited overlying inner surface of the plurality of gate trenches to serve as a gate oxide 762, onto which doped poly-silicon is deposited filling the plurality of gate trenches and then etched back by CMP (Chemical Mechanical Polishing) or plasma etching to form a plurality of first trenched gates 763, at least a wider second trenched gate 751, a plurality of third trenched gates 753. Then, over the entire top surface, a step of P body dopant Ion Implantation is carried out for the formation of P body regions 764 followed by a P body dopant diffusion for drive-in.

In FIG. 20B, an un-doped SRO layer 765-1 and a BPSG or PSG layer 765-2 are successively deposited onto top surface of the epitaxial layer 760. Then, after a contact mask (not shown) is applied, the un-doped SRO layer 765-1 and the BPSG or PSG layer 765-2 are etched to define a plurality of contact openings (766˜1˜766˜3). Then, a step of n+ source dopant Ion Implantation is carried out over entire surface for the formation of n+ source region 767 followed by a diffusion (lateral diffusion and vertical diffusion) of n+ source dopant for drive-in.

In FIG. 20C, a step of dry silicon etch is then carried out to etch the contact openings (766˜1˜766˜3): through the n+ source region 767 and into the body region 304; into the doped poly-silicon in the second wider trenched gate 751, respectively. After that, BF2 Ion Implantation is carried out over entire top surface to form p+ body contact area 768 followed by a step of RTA (Rapid Thermal Annealing) to active implanted dopant.

In FIG. 20D, wet etching in dilute HF is first carried out to enlarge the trenched contact width in the BPSG or PSG layer 765-2. Then, a barrier layer 769 composed of Ti and a first TiN layer is deposited along inner surface of all the contact openings (766-1˜766˜3) and covering outer surface of the BPSG or PSG layer 765-2. Next, a step of RTA or furnace anneal is performed to form TiSi₂. Then, onto the barrier layer 769, a second TiN layer 770 is deposited.

In FIG. 20E, a filling-in material W is deposited onto the second TiN layer 770, and then the material W and the second TiN layer 770 are successively etched back to form trenched source-body contact structure 771 and trenched gate contact structure 752. Then, a metal layer of Al alloys or Cu alloys padded by a resistance reduction layer 773 of Ti is deposited and patterned by a metal mask (not shown) to form source metal 774 and gate metal 775 by metal etching.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET comprising a plurality of transistor cells with each comprising:
a substrate of a first conductivity type;
an epitaxial layer of said first conductivity type grown on said substrate, said epitaxial layer having a lower doping concentration than said substrate;
a plurality of first trenched gates formed in an active area surrounded by source regions of said first conductivity type encompassed in body regions of a second conductivity type; and
a plurality of trenched source-body contact structures penetrating through a contact interlayer, said source regions and extending into said body regions, wherein each of said trenched source-body contact structure comprises a metal plug padded by a barrier layer composed of Ti and a first TiN layer, and
a second TiN layer disposed after formation of said barrier layer and a step of RTA or furnace anneal.

2. The trench MOSFET of claim 1, wherein said source regions each has uniform doping concentration and uniform junction depth from sidewalls of said trenched source-body contact structures to adjacent channel regions at a same distance from a top surface of said epitaxial layer.

3. The trench MOSFET of claim 1, wherein said source regions each has greater doping concentration and greater junction depth along sidewalls of said trenched source-body contact structures than along adjacent channel regions at a same distance from a top surface of said source regions, and doping concentration of said source regions each has a Gaussian-distribution from said trenched source-body contact structures to adjacent channel regions.

4. The trench MOSFET of claim 1 further comprising at least one second wider trenched gate adjacent to said active area.

5. The trench MOSFET of claim 1 further comprising a termination area composed of multiple third trenched floating gates surrounded by said body regions without having said source regions.

6. The trench MOSFET of claim 1, wherein said metal plug is a tungsten plug connecting with a source metal whereon.

7. The trench MOSFET of claim 1, wherein said metal plug is formed by a source metal directly filling into a contact opening and padded by said barrier layer and said second TiN layer.

8. A method of forming a semiconductor device comprising a plurality of first trenched gates gate surrounded by source regions of a first conductivity type near a top surface of a silicon layer of said first conductivity type encompassed in body regions of a second conductivity type in active area, said method comprising:
applying a trench mask on said silicon layer and formation of a plurality of said first trenched gates in said active area, and at least a second trenched gates having wider gate trench than said first trenched gates in a gate runner metal area, and multiple third trenched gates in a termination area;
after formation of said body regions, depositing a contact insulation layer on the top surface of said silicon layer;
applying a contact mask and following with a dry oxide etching to remove said contact insulation layer from contact openings;
implanting said silicon layer with a source dopant of said first conductivity type through said contact openings and diffusing said source dopant to form said source regions in said active area, thereby a source mask is saved;
carrying out a dry silicon etch to make said contact openings penetrating through said source regions and extending into said body region.
depositing a barrier layer of Ti and a first TiN layer along inner surface of said contact openings;
performing a step of RTA or furnace anneal;
depositing a second TiN layer onto said barrier layer before filling with W plug into said contact openings.

9. The method of claim 8 further comprising: after etching said contact openings into said body regions, a body contact ion implantation is carried out to form body contact area of said second conductivity type at least around bottom of said contact openings.
